(19) United States
(12) Patent Application Publication
(10) Pub. No.: US 2025/0365910 A1
(43) Pub. Date: Nov. 27, 2025

(54) TAPE CONVEYANCE ASSISTANCE DEVICE AND AUTOMATIC TAPE LOADING DEVICE

(71) Applicant: FUJI CORPORATION, Chiryu (JP)

(72) Inventors: Isao TSUZUKI, Kariya-shi (JP); Yukinori TAKADA, Anjo-shi (JP)

(73) Assignee: FUJI CORPORATION, Chiryu (JP)

(21) Appl. No.: 18/728,182

(22) PCT Filed: Feb. 22, 2022
(86) PCT No.: PCT/JP2022/007245

§ 371 Date: Jul. 11, 2024

(51) Int. Cl. H05K 13/04; H05K 13/02

(52) U.S. Cl. CPC H05K 13/0419; H05K 13/021

(57) ABSTRACT

A tape conveyance assistance device assists a carrier tape, which is formed by bonding a cover tape to an upper surface side of a base tape provided with a cavity in which a component is accommodated at a constant pitch, to be conveyed along a conveyance path of a tape feeder in a loading process of loading the carrier tape on the tape feeder, the tape conveyance assistance device includes a roller rotatably provided in a state in which the carrier tape is biased to move along the conveyance path, and a recessed portion configured to temporarily accommodate a front end of the carrier tape conveyed along the conveyance path in the loading process is provided on a peripheral surface of the roller.

### TECHNICAL FIELD

The present description relates to a tape conveyance assistance device and an automatic tape loading device.

### BACKGROUND ART

Conventionally, for example, an automatic tape loading device disclosed in Patent Literature 1 is known. The conventional automatic tape loading device includes a tape conveyance device that conveys a carrier tape wound around a tape reel, and the tape conveyance device conveys carrier tape to a component supply position provided in the tape feeder, thereby loading the carrier tape into the tape feeder. Here, the tape conveyance device includes a conveyance roller including a cylindrical drive roller and a driven roller, and conveys the carrier tape in a state where the carrier tape is passed between the drive roller and the driven roller.

### PATENT LITERATURE

Patent Literature 1: Japanese Patent No. 5877891

### SUMMARY OF THE INVENTION

### Technical Problem

There is an embossed tape in which a cavity for accommodating a component to be supplied to a base tape forming a carrier tape is provided as a carrier tape to be conveyed by a tape conveyance device. A thickness of the embossed tape is larger than that of a paper tape having no cavity.

In the tape conveyance device of the conventional automatic tape loading device, the conveyance roller has a cylindrical shape. In this case, when a thin carrier tape such as a paper tape is conveyed, the carrier tape can be easily passed between the drive roller and the driven roller, and the conveyance roller can smoothly convey the carrier tape.

However, when a thick carrier tape such as an embossed tape is conveyed, the carrier tape cannot be easily passed between the drive roller and the driven roller (cannot be inserted into), and as a result, the carrier tape may stagnate in front of the conveyance roller. As a result, there is a case where a work burden and a work time required for loading process for loading a carrier tape having a large thickness into the tape feeder are increased, and there is room for improvement.

An object of the present description is to provide a tape conveyance assistance device and an automatic tape loading device for assisting conveyance of a carrier tape in loading process.

### Solution to Problem

The present description discloses a tape conveyance assistance device for assisting a carrier tape, which is formed by bonding a cover tape to an upper surface side of a base tape provided with a cavity in which a component is accommodated at a constant pitch, to be conveyed along a conveyance path of a tape feeder in a loading process of loading the carrier tape on the tape feeder, the tape conveyance assistance device includes a roller rotatably provided in a state in which the carrier tape is biased to move along the conveyance path, and a recessed portion configured to temporarily accommodate a front end of the carrier tape conveyed along the conveyance path in the loading process is provided on a peripheral surface of the roller.

With the tape conveyance assistance device, an auxiliary roller having the recessed portion biases the carrier tape without stagnating, in other words, can convey the carrier tape by applying an appropriate propulsive force to the carrier tape. Accordingly, in the loading process, a success rate, which represents a probability of properly loading the carrier tape on the tape feeder, can be improved, and as a result, it is possible to reduce a work burden and a work time required for the loading process.

### BRIEF DESCRIPTION OF DRAWINGS

FIG. 1 is a top view illustrating a configuration of an automatic tape loading device.

FIG. 2 is a top view schematically illustrating a carrier tape.

FIG. 3 is a cross-sectional view taken along line III-III of FIG. 2.

FIG. 4 is a perspective view schematically illustrating a tape feeder.

FIG. 5 is a perspective view illustrating configurations of a tape conveyance device and a tape conveyance assistance device.

FIG. 6 is a side view illustrating the configuration of the tape conveyance assistance device of FIG. 5.

FIG. 7 is a view illustrating an operation of the tape conveyance assistance device of FIG. 6.

FIG. 8 is a view illustrating the operation of the tape conveyance assistance device of FIG. 6.

FIG. 9 is a view illustrating the operation of the tape conveyance assistance device of FIG. 6.

### DESCRIPTION OF EMBODIMENTS

Hereinafter, a tape conveyance assistance device and an automatic tape loading device will be described with reference to the drawings. In the present embodiment, a case where the tape conveyance assistance device is provided in an automatic tape loading device will be described as an example.

### 1. Automatic Tape Loading Device 1

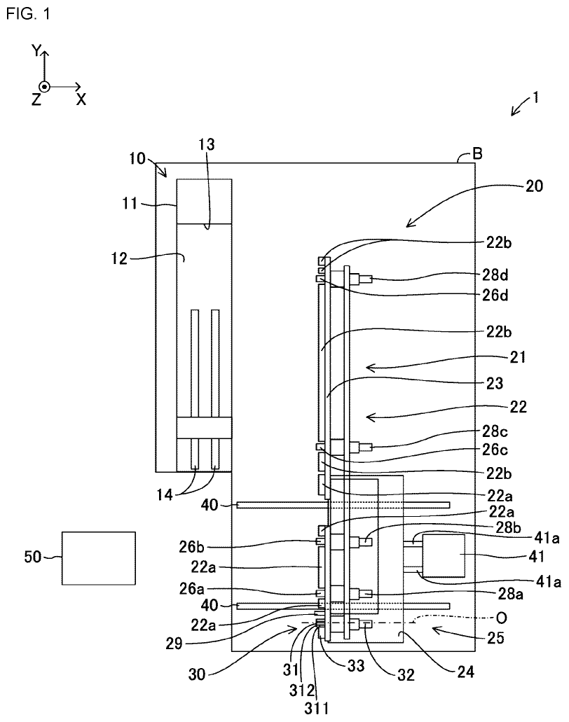

As illustrated in FIGS. 1 to 4, automatic tape loading device 1 is a device that automatically loads carrier tape T wound around tape reel R (hereinafter, also simply referred to as “reel R”) attached to tape feeder F (hereinafter, also simply referred to as “feeder F”) on feeder F. In the following description, a tape conveyance direction when loading carrier tape T is a Y direction, a horizontal direction orthogonal to the Y direction is an X direction, and a vertical direction orthogonal to the Y direction is a Z direction.

As illustrated in FIG. 1, automatic tape loading device 1 includes feeder holding table 10 that holds feeder F, tape conveyance device 20 and tape conveyance assistance device 30 that convey carrier tape T, and control device 50. Feeder holding table 10 is disposed on base B such that feeder F to be held faces the Y direction. Control device 50 includes a microcomputer as a main component and totally controls the operation of automatic tape loading device 1.

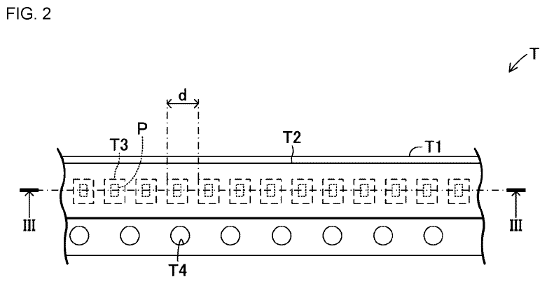

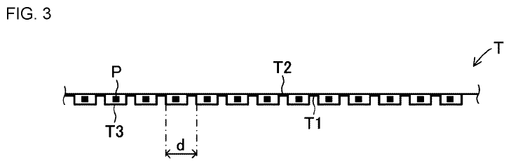

Here, carrier tape T wound around reel R and feeder F will be described with reference to FIGS. 2, 3, and 4. First, as illustrated in FIGS. 2 and 3, in carrier tape T, cover tape T2 is bonded to the upper surface side of base tape T1, and cavity T3 for accommodating component P is provided at constant pitch d on base tape T1. That is, as illustrated in FIG. 3, carrier tape T of the present embodiment is an embossed tape having a large thickness in which the bottom portion of cavity T3 protrudes from the lower surface of base tape T1. A large number of feed holes T4 are provided along one side edge of carrier tape T. In general, base tape T1 is formed using a flexible material such as a paper material or a resin, and cover tape T2 is formed using a transparent and flexible high molecular film or the like.

There are multiple types of reels R in which materials of carrier tapes T to be wound are different and tape width dimensions of carrier tape T and width dimensions of reel R are different. There are also multiple types of feeder F on which reels R of different types are loaded. Therefore, although not illustrated, an identification code (for example, a barcode or a two-dimensional code) for identifying individual reel R and identifying the type of feeder F on which reel R is to be loaded is displayed on each of reels R.

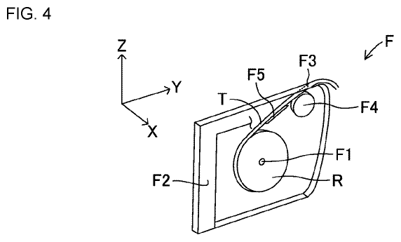

Feeder F is loaded with reel R around which carrier tape T is wound, and supplies component P by feeding carrier tape T in a component mounter (not illustrated). As illustrated in FIG. 4, feeder F is formed thin and has a small width in the X direction (for example, left-right direction). Feeder F has reel holding shaft F1 protruding rightward from the side plate on the left side in FIG. 4 at a substantially central position when viewed from a lateral side. Reel holding shaft F1 is fitted into a center hole formed at a center of reel R to detachably and rotatably hold reel R. A central portion of right side plate F2 of feeder F is widely opened in order to facilitate attachment and detachment of reel R.

Feeder F further includes component supply position F3, sprocket F4, tape feed guide F5, and a tape peeling section (not illustrated). Component supply position F3 is provided near the rear end of the upper surface of feeder F. Sprocket F4 is rotatably provided on the front side of component supply position F3. The teeth of sprocket F4 are engaged with feed holes T4 of carrier tape T. Sprocket F4 is intermittently driven by a drive motor (not illustrated) and feeds carrier tape T at constant pitches. Tape feed guide F5 forms a conveyance path for guiding carrier tape T toward sprocket F4. The tape peeling section causes component supply position F3 to pass in a state (so-called semi-peeling state) in which one side edge of cover tape T2 constituting carrier tape T is separated from base tape T1, and enables component P to be taken out in the component mounter. After passing through component supply position F3, carrier tape T is cut by, for example, a tape cutting device provided in the component mounter.

Further, although not illustrated, an identification code (for example, a barcode or a two-dimensional code) for identifying the type of feeder F is displayed on each of the feeders F. Feeder F is provided with a feeder control section (not illustrated). The feeder control section stores identification information for identifying feeder F (and reel R), and controls a component supply operation. When feeder F is held by feeder holding table 10 of automatic tape loading device 1, the feeder control section can communicate with the outside (for example, control device 50) by automatically fitting a connector (not illustrated).

As illustrated in FIG. 1, feeder holding table 10 includes pedestal 11 that holds feeder F (see FIG. 4) in which reel R is attached to the reel holding shaft F1. Pedestal 11 includes placement section 12 on which the bottom surface of feeder F is placed, and abutment section 13 on which the rear end surface of feeder F abuts. In the present embodiment, pair of support guides 14 is provided on placement section 12 to sandwich both side surfaces of the lower portion of feeder F. Although not illustrated, a power supply section that supplies power to feeder F and a position determination section that determines the position of feeder F are provided in abutment section 13.

### 2. Tape Conveyance Device 20

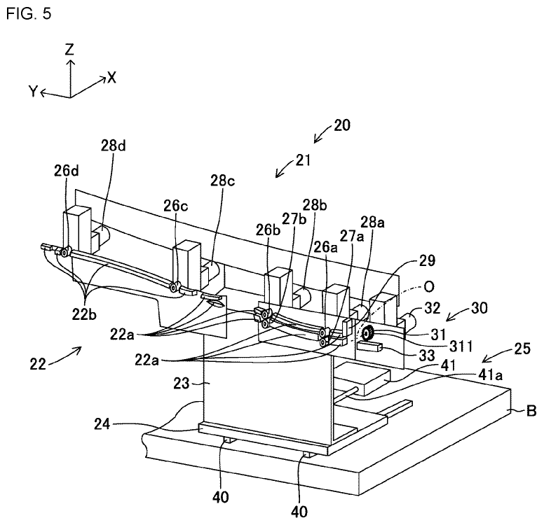

As illustrated in FIG. 5, tape conveyance device 20 includes feed device 21 that conveys carrier tape T fed out from reel R, guide 22 that guides conveyed carrier tape T, support plate 23 that supports feed device 21 and guide 22, pedestal 24 on which support plate 23 is placed and fixed, conveyance movement device 25 that moves pedestal 24 in the X direction, and sensor 29 that detects a leading end portion of carrier tape T.

Feed device 21 includes multiple (four in the present embodiment) drive rollers 26a, 26b, 26c, and 26d disposed along the tape conveyance direction (conveyance path), and driven rollers 27a and 27b disposed on the opposite side to abut on drive rollers 26a and 26b from below and rotating in accordance with the movement of carrier tape T. Drive rollers 26a and 26b and driven rollers 27a and 27b form a “conveyance roller” that conveys carrier tape T along the conveyance path.

Four drive rollers 26a, 26b, 26c, and 26d are arranged side by side in the Y direction, that is, the tape conveyance direction along the conveyance path at predetermined intervals, and are supported by support plate 23. Driven rollers 27a and 27b are biased toward drive rollers 26a and 26b by springs (not illustrated), respectively. Feed device 21 includes drive motors 28a, 28b, 28c, and 28d for rotationally driving drive rollers 26a, 26b, 26c, and 26d.

Guide 22 is supported by support plate 23 to be positioned in front of drive roller 26a at the start end, between four drive rollers 26a, 26b, 26c, and 26d, and ahead of drive roller 26d at the terminal end. More specifically, guide 22a in front of drive roller 26a at the start end, ahead of drive roller 26b arranged at the second position, and between drive rollers 26a and 26b is formed by a pair of guides vertically in accordance with the arrangement of drive rollers 26a and 26b and driven rollers 27a and 27b. Guide 22b in front of drive roller 26c arranged at the third position, ahead of drive roller 26d at the terminal end, and between drive rollers 26c and 26d is formed by one guide in accordance with the arrangement of drive rollers 26c and 26d.

When feeder F is held by feeder holding table 10, tape feed guide F5 of feeder F is provided to be positioned from front of drive roller 26c arranged at the third position to ahead of drive roller 26d at the terminal end. Accordingly, carrier tape T to be conveyed is guided through the gap between guide 22b and tape feed guide F5, that is, the conveyance path. Tape feed guide F5 is not provided from front of drive roller 26a at the start end to ahead of drive roller 26b arranged at the second position. Thus, carrier tape T to be conveyed is guided through the gap between pair of guides 22a, that is, the conveyance path.

Conveyance movement device 25 includes pair of rails 40 and air cylinder 41. Pair of rails 40 is provided on base B to extend in the X direction at predetermined intervals. Pedestal 24 is disposed on pair of rails 40 to be slidable in the X direction. Air cylinder 41 is disposed between pair of rails 40 on base B and is connected to an air supply source (not illustrated), and cylinder rod 41a is connected to pedestal 24.

Sensor 29 is supported by support plate 23 to be positioned above a tape entrance of pair of guides 22a disposed in front of drive roller 26a at the start end (downstream side in the tape conveyance direction), and detects whether a leading end of carrier tape T has entered the tape entrance. Sensor 29 is connected to control device 50. Thus, control device 50 controls the driving of drive motors 28a, 28b, 28c, and 28d, that is, the rotation of drive rollers 26a, 26b, 26c, and 26d, by acquiring the detection signal of sensor 29. Further, control device 50 controls the rotation of sprocket F4 in cooperation with, for example, the feeder control section by acquiring the detection signal of sensor 29.

### 3. Tape Conveyance Assistance Device 30

Tape conveyance assistance device 30 is a device that assists carrier tape T to be conveyed along the conveyance path in a loading process for loading carrier tape T on feeder F mainly by tape conveyance device 20. Tape conveyance assistance device 30 is disposed downstream of drive rollers 26a and 26b of feed device 21 in the tape conveyance direction in the conveyance path of carrier tape T. Like tape conveyance device 20, tape conveyance assistance device 30 is also supported by support plate 23.

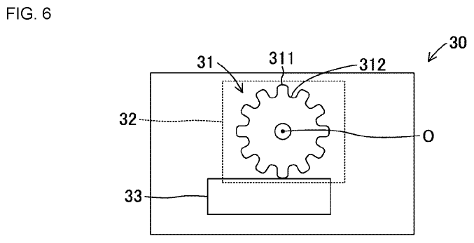

Tape conveyance assistance device 30 conveys carrier tape T fed out from reel R toward feed device 21. Therefore, as illustrated in FIGS. 5 and 6, tape conveyance assistance device 30 includes auxiliary roller 31, drive motor 32 as a drive source, and guide 33.

As illustrated in FIG. 6, auxiliary roller 31 includes recessed portion 311 and protruding portion 312 which are alternately arranged along the roller circumferential direction and are formed on the peripheral surface along the direction of axis O of auxiliary roller 31. Multiple recessed portions 311 are formed to temporarily accommodate the leading end of carrier tape T from an outer peripheral surface including an apex of protruding portion 312 toward the inside in the radial direction. The formation intervals of recessed portions 311 in the roller circumferential direction are formed at equal intervals based on pitch d of cavities T3 of carrier tape T illustrated in FIGS. 2 and 3. Thus, as will be described later, recessed portion 311 can convey carrier tape T toward feed device 21, that is, toward the upstream side in the tape conveyance direction while reliably temporarily accommodating the front end of carrier tape T approaching auxiliary roller 31.

Here, auxiliary roller 31 is biased toward guide 33 by a spring (not illustrated), that is, when carrier tape T is supported by guide 33, auxiliary roller 31 is biased along the thickness direction of carrier tape T. Thus, when carrier tape T is conveyed by rotation, auxiliary roller 31 can convey carrier tape T supported by guide 33 in a state where the carrier tape T is pressed along the thickness direction. That is, auxiliary roller 31 can generate an appropriate friction force between auxiliary roller 31 and cover tape T2 of carrier tape T.

Drive motor 32 is, for example, a stepping motor. Drive motor 32 is driven and controlled by control device 50, and for example, drives and rotates auxiliary roller 31 to synchronize with (more preferably, to rotate slightly faster than) the rotation of drive rollers 26a, 26b, 26c, and 26d of feed device 21 disposed on the upstream side. Accordingly, auxiliary roller 31 can reliably convey carrier tape T along the conveyance path (tape conveyance direction) in a state where carrier tape T is biased toward feed device 21.

### 5. Operation of Tape Conveyance Device 20 and Tape Conveyance Assistance Device 30

Next, operations of tape conveyance device 20 and tape conveyance assistance device 30 will be described. In the loading process, first, tape conveyance assistance device 30 operates to convey carrier tape T toward the tape entrance of tape conveyance device 20. Therefore, with the start of the loading process, control device 50 drives drive motor 32 of tape conveyance assistance device 30 to rotate auxiliary roller 31.

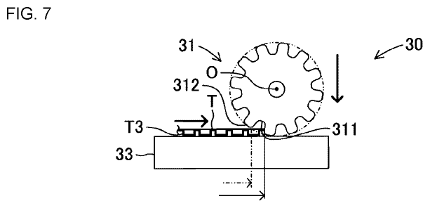

As illustrated in FIG. 7, in tape conveyance assistance device 30, when the front end of carrier tape T is supplied in a state of being biased toward auxiliary roller 31, recessed portion 311 of auxiliary roller 31 temporarily accommodates the front end of carrier tape T. That is, auxiliary roller 31 causes the front end of carrier tape T to travel toward the inside of auxiliary roller 31, in other words, toward the inside of recessed portion 311 formed along the circumferential direction and the direction of axis O and to be accommodated there.

For example, as illustrated by a two-dot chain line in FIG. 7, when auxiliary roller 31 is in a cylindrical shape not having recessed portion 311 and protruding portion 312, the front end of carrier tape T comes into contact with the outer peripheral surface of auxiliary roller 31. In this case, the front end of carrier tape T cannot be accommodated inside auxiliary roller 31. That is, in the case where recessed portion 311 indicated by an arrow (thin line) of a solid line in FIG. 7 is provided, the length of carrier tape T entering the inside of auxiliary roller 31 is longer, by a length by which recessed portion 311 accommodates the front end of carrier tape T, that than in the case where recessed portion 311 indicated by the arrow (thin line) of the two-dot chain line in FIG. 7 is not provided.

Multiple recessed portions 311 are formed at equal intervals along the circumferential direction of auxiliary roller 31. For this reason, when the front end of carrier tape T is not accommodated in recessed portion 311, for example, when the front end abuts on protruding portion 312, auxiliary roller 31 is rotated by a small amount by drive motor 32 or manually. Accordingly, auxiliary roller 31 can accommodate the front end of inserted carrier tape T in recessed portion 311.

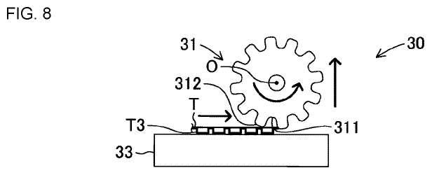

Subsequently, when auxiliary roller 31 further rotates while carrier tape T is biased toward auxiliary roller 31, as illustrated in FIG. 8, protruding portion 312 adjacent to recessed portion 311 accommodating the front end of carrier tape T in the circumferential direction abuts on the upper surface side of carrier tape T. When auxiliary roller 31 further rotates, protruding portion 312 presses the upper surface of carrier tape T as indicated by a straight arrow in FIG. 8. As a result, a reaction force is generated in auxiliary roller 31, and auxiliary roller 31 moves against the biasing force of the spring in a direction away from guide 33 in the thickness direction of carrier tape T.

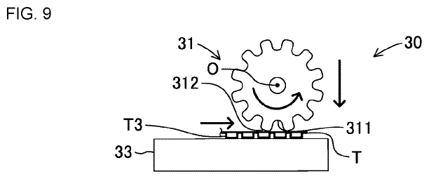

When auxiliary roller 31 further rotates, as illustrated in FIG. 9, auxiliary roller 31 entirely rides onto carrier tape T. In a state where auxiliary roller 31 rides onto carrier tape T, auxiliary roller 31 (more specifically, protruding portion 312) is caused to press carrier tape T toward guide 33 by the biasing force of the spring.

Accordingly, auxiliary roller 31 can bias carrier tape T along the tape conveyance direction (conveyance path) by being rotated by the driving force of drive motor 32. In this state, the driving force of drive motor 32 is transmitted to carrier tape T as a propulsive force by the friction force between protruding portion 312 disposed along the circumferential direction of auxiliary roller 31 and the cover tape Tb of carrier tape T. Thus, carrier tape T is conveyed by being biased toward the upstream side along the tape conveyance direction (conveyance path), that is, toward feed device 21 of tape conveyance device 20.

In tape conveyance device 20, sensor 29 detects entry of carrier tape T conveyed by tape conveyance assistance device 30 into the tape entrance. Thus, control device 50 drives drive motors 28a, 28b, 28c, and 28d of feed device 21.

In feed device 21, carrier tape T is supplied in a state of being biased along the tape conveyance direction by auxiliary roller 31 of tape conveyance assistance device 30. Thus, driven rollers 27a and 27b move in a direction away from drive rollers 26a and 26b against the biasing force of the spring, by the biasing force of carrier tape T, that is, the propulsive force. Thus, carrier tape T enters between drive rollers 26a and 26b and driven rollers 27a and 27b. As drive rollers 26a and 26b rotate by the driving force of drive motors 28a and 28b, carrier tape T is conveyed toward drive rollers 26c and 26d on the upstream side, and is finally loaded in a state of being pitch-fed by sprocket F4 of feeder F.

As can be understood from the above description, tape conveyance assistance device 30 assists carrier tape T to be conveyed along the conveyance path of tape feeder F in the loading process of loading carrier tape T, which is formed by bonding cover tape T2 to the upper surface side of base tape T1 provided with cavity T3 in which component P is accommodated at a constant pitch d, on tape feeder F. Tape conveyance assistance device 30 includes auxiliary roller 31 that is rotatably provided in a state in which carrier tape T is biased to move along the conveyance path, and recessed portion 311 that temporarily accommodates the front end of carrier tape T conveyed along the conveyance path in the loading process is provided on the peripheral surface of auxiliary roller 31.

With tape conveyance assistance device 30, auxiliary roller 31 having recessed portion 311 biases carrier tape T, in other words, applies an appropriate propulsive force to carrier tape T, which makes it possible to convey carrier tape T toward tape conveyance device 20. Accordingly, in the loading process, a success rate, which represents a probability of properly loading carrier tape T on tape feeder F, can be improved, and as a result, it is possible to reduce a work burden and a work time required for the loading process.

### 6. Modification Example

In the above-described embodiment, tape conveyance assistance device 30 is provided in automatic tape loading device 1. However, in addition to automatic tape loading device 1, it is also possible to provide tape conveyance assistance device 30 in a device requiring the process for conveying carrier tape T along the conveyance path (tape conveyance direction).

Further, in the above-described embodiment, tape conveyance assistance device 30 is provided in automatic tape loading device 1 that automatically conveys carrier tape T wound around reel R to component supply position F3 of feeder F. That is, in the above-described embodiment, tape conveyance assistance device 30 feeds out carrier tape T wound around reel R, and continuously conveys fed carrier tape T toward feed device 21 of tape conveyance device 20.

Alternatively, for example, after an operator feeds out carrier tape T from reel R using tape conveyance assistance device 30, carrier tape T fed by the operator may be supplied (conveyed) to feed device 21 of tape conveyance device 20. Even in this case, the same effects as those of the above-described embodiment can be obtained.

In the above-described embodiment, auxiliary roller 31 of tape conveyance assistance device 30 has multiple recessed portions 311 along the circumferential direction. However, it is not necessary to provide multiple recessed portions 311 on the peripheral surface of auxiliary roller 31. That is, it is also possible to provide only one recessed portion 311 on the peripheral surface of auxiliary roller 31. Even in this case, since recessed portion 311 can accommodate the front end of carrier tape T by aligning recessed portion 311 of auxiliary roller 31 with the front end of carrier tape T, the same effects as those of the above-described embodiment can be expected.

In the above-described embodiment, recessed portions 311 of auxiliary roller 31 are provided at equal intervals along the circumferential direction. However, the formation intervals between recessed portions 311 are not limited to equal intervals. Even in the case where recessed portions 311 are not provided at equal intervals, since recessed portion 311 can accommodate the front end of carrier tape T and ride onto the upper surface of carrier tape T, the same effects as those of the above-described embodiment can be expected.

Furthermore, in the above-described embodiment, multiple recessed portions 311 (and protruding portions 312) are formed along the direction of axis O of auxiliary roller 31. However, for example, in a state in which the tape conveyance direction (conveyance path) of carrier tape T is not orthogonal to axis O of auxiliary roller 31, recessed portion 311 (and protruding portion 312) can be formed without aligning recessed portion 311 (and protruding portion 312) along axis O of auxiliary roller 31. Even in this case, since recessed portion 311 can accommodate the front end of carrier tape T, the same effects as those of the above-described embodiment can be expected.

### REFERENCE SIGNS LIST

1: automatic tape loading device, 10: feeder holding table, 20: tape conveyance device, 21: feed device, 22, 22a, 22b: guide, 23: support plate, 24: pedestal, 25: conveyance movement device, 26a, 26b: drive roller (conveyance roller), 26c, 26d: drive roller, 27a, 27b: driven roller (conveyance roller), 28a, 28b, 28c, 28d: drive motor, 30: tape conveyance assistance device, 31: auxiliary roller (roller), 32: drive motor (drive source), 33: guide, 50: control device, T: carrier tape, T1: base tape, T2: cover tape, T3: cavity, R: tape reel, F: tape feeder, F3: component supply position, F5: tape feed guide, d: pitch, O: axis

1. A tape conveyance assistance device for assisting a carrier tape, which is formed by bonding a cover tape to an upper surface side of a base tape provided with a cavity in which a component is accommodated at a constant pitch, to be conveyed along a conveyance path of a tape feeder in a loading process of loading the carrier tape on the tape feeder, the tape conveyance assistance device comprising:
a roller rotatably provided in a state in which the carrier tape is biased to move along the conveyance path,
wherein a recessed portion configured to temporarily accommodate a front end of the carrier tape conveyed along the conveyance path in the loading process is provided on a peripheral surface of the roller.

2. The tape conveyance assistance device according to claim 1, wherein the roller is driven by a drive source.

3. The tape conveyance assistance device according to claim 1, wherein the recessed portion is provided along an axial direction of the roller.

4. The tape conveyance assistance device according to claim 1, wherein multiple recessed portions are provided along a circumferential direction of the roller.

5. The tape conveyance assistance device according to claim 1, further comprising a conveyance roller configured to convey the carrier tape along the conveyance path,
wherein the roller is an auxiliary roller disposed downstream of the conveyance roller in the conveyance path.

6. The tape conveyance assistance device according to claim 5, wherein the conveyance roller has a drive roller configured to perform drive and a driven roller disposed on a side opposite to the drive roller in a thickness direction of the carrier tape and configured to rotate as the carrier tape moves.

7. The tape conveyance assistance device according to claim 6, wherein multiple drive rollers and driven rollers are provided along the conveyance path.

8. The tape conveyance assistance device according to claim 1, wherein the carrier tape is an embossed tape having a bottom portion of the cavity protruding from a lower surface of the base tape.

9. An automatic tape loading device comprising the tape conveyance assistance device according to claim 1,
wherein the automatic tape loading device is configured to convey the carrier tape to a component supply position which is provided in the tape feeder and at which the component is supplied, to thereby load the carrier tape.
